(19) United States
(12) Patent Application Publication
(10) Pub. No.: US 2014/0110248 A1
(43) Pub. Date: Apr. 24, 2014

(54) CHAMBER PASTING METHOD IN A PVD CHAMBER FOR REACTIVE RE-SPUTTERING DIELECTRIC MATERIAL

(71) Applicant: Applied Materials, Inc., Santa Clara, CA (US)

(72) Inventors: Yong CAO, San Jose, CA (US); Thanh X. NGUYEN, San Jose, CA (US); Muhammad M. RASHEED, San Jose, CA (US); Xianmin TANG, San Jose, CA (US)

(73) Assignee: Applied Materials, Inc., Santa Clara, CA (US)

(21) Appl. No.: 14/036,057

(22) Filed: Sep. 25, 2013

Related U.S. Application Data
(60) Provisional application No. 61/715,395, filed on Oct. 18, 2012.

(51) Int. Cl. C23C 14/34

(52) U.S. Cl. CPC C23C 14/34
USPC 204/192.22

(57) ABSTRACT

According to embodiments provide a method for forming dielectric films using physical vapor deposition chamber. Particularly, a pasting process may be performed to apply a conductive coating over inner surfaces of the physical vapor deposition chamber. The pasting process may be performed under adjusted process parameters, such as increased spacing and/or increased chamber pressure. The adjusted parameters allow the conductive coating to be formed more efficiently and effectively.

### CROSS-REFERENCE TO RELATED APPLICATIONS

This application claims priority to U.S. Provisional Patent Application Ser. No. 61/715,395, filed on Oct. 18, 2012, which herein is incorporated by reference.

### BACKGROUND

1. Field of the Invention

Embodiments of the present invention relate to apparatus and methods for processing substrates in a physical vapor deposition chamber. Particularly, embodiments of the present invention relate to pasting inner surfaces of a physical vapor deposition chamber.

2. Description of the Related Art

In semiconductor processing, physical vapor deposition (PVD) is a conventionally used process for depositing a thin film. A PVD process generally includes bombarding a target comprising a source material with ions from a plasma, causing the source material to be sputtered from the target. The ejected source material is then accelerated towards a substrate being processed via a voltage bias, resulting in a deposition of the source material with or without reaction with other reactant.

In recent years, PVD process has been increasingly used to deposit dielectric materials replacing chemical vapor deposition (CVD). Compared to dielectric films formed by CVD, dielectric films formed by PVD have less contamination, thus, higher quality.

However, depositing dielectric material in a PVD chamber is accompanied by inner surfaces of the PVD chamber slowly coated by a non-conductive dielectric material. Because inner shields of PVD chambers function as system anodes during processing, the dielectric coating on the inner surfaces can cause variation in circuit impedance and voltage distribution. The dielectric coating may also change plasma distribution inside the PVD chamber thus negatively impacts deposition rate and uniformity of film thickness. Ultimately, the dielectric coating may even cause circuit interruption and disappearing anode problems.

Therefore, there is need for apparatus and methods for maintaining the inner surfaces of a PVD chamber conductive during deposition of dielectric materials.

### SUMMARY

Embodiments of the present invention provide methods for pasting a conductive layer on inner surfaces of a PVD chamber for depositing dielectric materials on substrates.

One embodiment of the present invention provides a method for forming dielectric material. The method includes depositing a dielectric material on one or more substrates disposed on a substrate support by sputtering a target with a plasma in a physical vapor deposition chamber, disposing a shutter disk over the substrate support, adjusting at least one of spacing between the substrate support and the target and a chamber pressure, and pasting a conductive layer over inner surfaces of the physical vapor deposition chamber by sputtering the target or the shutter disk.

Another embodiment of the present invention provides a method for forming a dielectric material. The method comprises flowing a reactive gas and an inert gas into a physical vapor deposition chamber having a target comprising a conductive material, generating a plasma of the reactive gas and the inert gas to sputter the target and depositing a dielectric film on the substrate disposed on a substrate support in the physical vapor deposition chamber by reactive sputtering, ceasing the flow of the reactive gas, adjusting at least one of a chamber pressure and a spacing between the substrate support and the target, and generating a plasma of the inert gas to sputter the target and to paste a conductive film on inner surfaces of the physical vapor deposition chamber.

Another embodiment of the present invention provides a method for forming a dielectric material. The method comprises flowing an inert gas into a physical vapor deposition chamber having a target comprising a dielectric material, generating a plasma of the inert gas to sputter the target and depositing a dielectric film on the substrate disposed on a substrate support in the physical vapor deposition chamber, disposing a first shutter disk over the target, disposing a second shutter disk over the substrate support, adjusting at least one of a chamber pressure and a spacing between the substrate support and the target; and generating a plasma of the inert gas to sputter the first shutter disk or the second shutter disk and to paste a conductive film on inner surfaces of the physical vapor deposition chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic sectional side view of a physical vapor deposition chamber in a substrate processing position according to one embodiment of the present invention.

FIG. 1B is a schematic sectional side view of the physical vapor deposition chamber of FIG. 1A in a chamber pasting position according to one embodiment of the present invention.

FIG. 2 is a flow chart reflecting a method for depositing a dielectric film using a physical vapor deposition chamber by reactive sputtering.

FIG. 3 is a sectional side view of a physical vapor deposition chamber in a chamber pasting position according to one embodiment of the present invention.

FIG. 4 is a flow chart reflecting a method for depositing a dielectric film using a physical vapor deposition chamber by sputtering.

To facilitate understanding, identical reference numerals have been used, where possible, to designate identical elements that are common to the figures. It is also contemplated that elements and features of one embodiment may be beneficially incorporated on other embodiments without further recitation.

### DETAILED DESCRIPTION

Embodiments of the present invention provide methods for depositing dielectric materials by physical vapor deposition chamber. More particularly, embodiments of the present invention provide methods for pasting a conductive material on inner surfaces of a physical vapor deposition chamber used for depositing dielectric materials. According to one embodiment of the present invention, after depositing a dielectric film on a plurality of substrates, a pasting process may be performed to apply a conductive coating over inner surfaces of the physical vapor deposition chamber. The pasting process according to embodiment of the present invention may be performed under adjusted process parameters, such as increased spacing and/or increased chamber pressure. The adjusted parameters allow the conductive coating to be formed more efficiently and effectively. Embodiments of the present invention may be used with a target comprising conductive material or a target comprising non-conductive dielectric material.

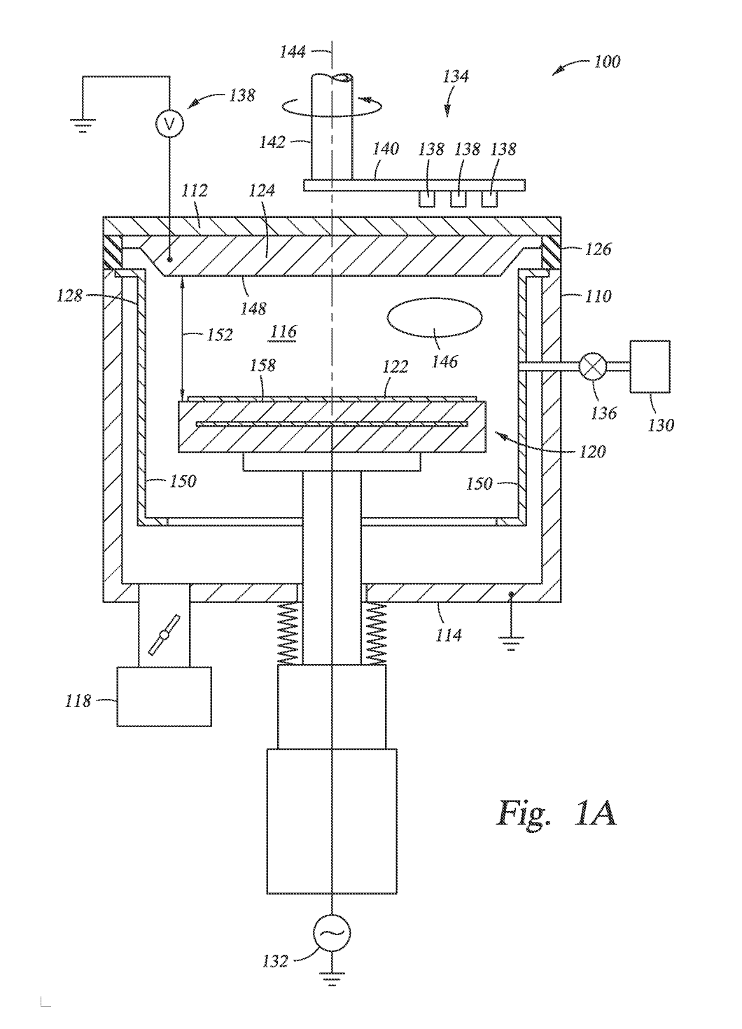

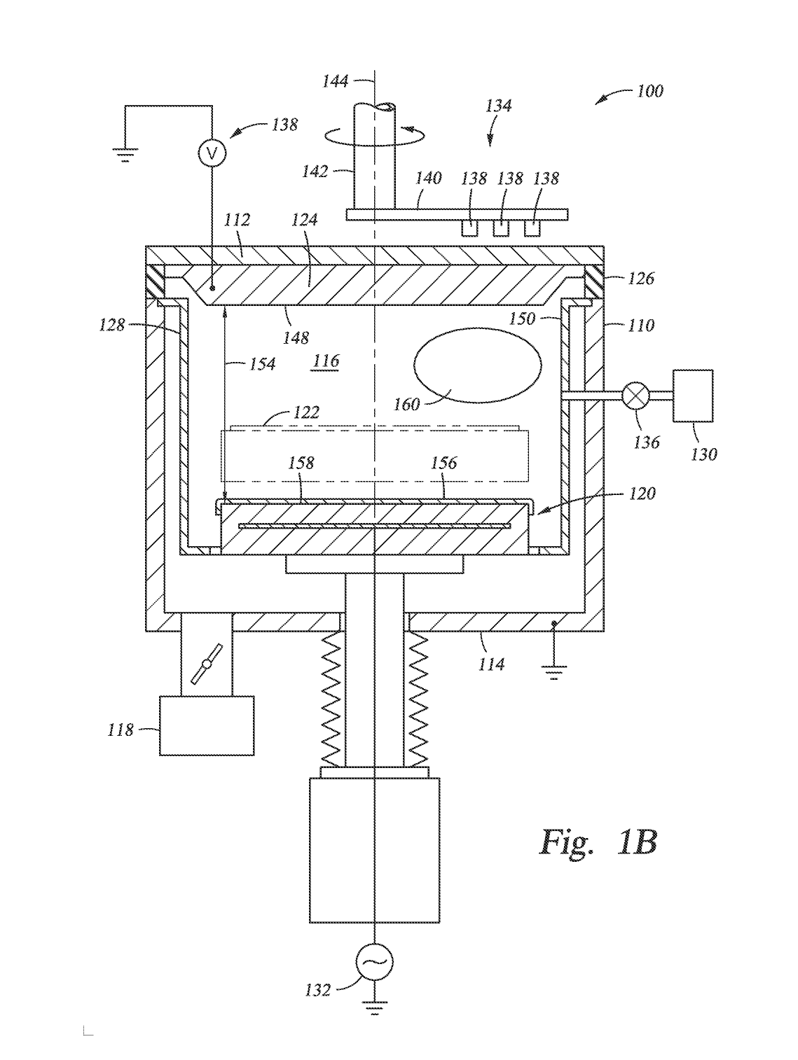

FIG. 1A is a schematic sectional side view of a physical vapor deposition chamber 100 in a substrate processing position according to one embodiment of the present invention. The physical vapor deposition chamber 100 includes chamber walls 110, a chamber lid 112, and a chamber bottom 114 defining a processing volume 116. The dielectric isolator 126 electronically insulates the chamber walls 110 from the chamber lid 112. The processing volume 116 may be maintained in a vacuum state during processing by a pumping system 118. The chamber walls 110, chamber lid 112 and the chamber bottom 114 may be formed from conductive materials, such as aluminum and stainless steel. A dielectric isolator 126 may be disposed between the chamber lid 112 and the chamber walls 110. The chamber walls 110 and the chamber bottom 114 may be electrically grounded during operation.

A substrate support 120 is disposed in the processing volume 116 for supporting a substrate 122. A radio frequency (RF) power source 132 may be coupled to the substrate support 120 for securing the substrate 122 on the substrate support 120. The substrate support 120 may move vertically in the processing volume 116 for substrate processing and for substrate transfer.

A target 124 is mounted on the chamber lid 112 and faces the substrate support 120. The target 124 includes materials to be deposited on the substrate 122 during processing. A direct current (DC) power source 138 is coupled to the target 124. The DC power source 138 may be used to generate a negative voltage or bias to the target 124 during operation. The DC power source 138 may be a pulsed power source. In one embodiment, the target 124 may be formed from one or more conductive materials for forming dielectric material by reactive sputtering. In one embodiment, the target 124 may include metal or alloy.

A shield assembly 128 is disposed within the processing volume 116. The shield assembly 128 surrounds the target 124 and the substrate 122 disposed over the substrate support 120 to retain processing chemistry within and protecting inner surfaces of chamber walls 110, chamber bottom 114 and other chamber components. In one embodiment, the shield assembly 128 may be electrically grounded during operation.

A gas source 130 is fluidly connected to the processing volume 116 to provide one or more processing gases. A flow controller 136 may be coupled between the gas source 130 and the processing volume 116 to control gas flow delivered to the processing volume 116.

A magnetron 134 may be disposed externally over the chamber lid 112. The magnetron 134 includes a plurality of magnets 138. The magnets 138 produces a magnetic field within the processing volume 116 near a front face 148 of the target 124 to generate a plasma 146 so that a significant flux of ions strike the target 124 causing sputter emission of the target material. The magnets 138 may rotate or linearly scan the target to increase uniformity of the magnetic field across the front face 148 of the target 124. As shown in FIG. 1A, the plurality of magnets 138 are mounted on a frame 140 connected to a shaft 142. The shaft 142 may be axially aligned with a central axis 144 of the substrate support 120 so that the magnets 138 rotate about the central axis 144.

The physical vapor deposition chamber 100 may be used to deposit a dielectric film. FIG. 1A schematically illustrates the physical vapor deposition chamber 100 in a processing position to deposit a dielectric film over the substrate 122. During deposition, a gas mixture including a reactive gas and an inert gas may be delivered to the processing volume 122 from the gas source 130. The plasma 146 formed near the front face 148 of the target 124 may include ions of the inert gas and the reactive gas. The ions in the plasma 146 strike the front face 148 of the target 124 sputtering the conductive material, which reacts with the reactive gas forming a dielectric material over the substrate 122.

Depending on the dielectric material to be formed on the substrate 122, the target 124 may be formed from a metal, such as Aluminum, Tantalum, Hafnium, Titanium, Copper, Niobium, or an alloy thereof. The reactive gas may include an oxidizing agent, a nitriding agent, or other reactive gases. According to one embodiment of the president invention, the reactive gas may include oxygen for forming a metal oxide, or nitrogen for forming a metal nitride. The inert gas may be argon.

During deposition, a spacing 152 between the substrate support 120 and the target 148 is configured to achieve desired deposition rate and/or film uniformity. In one embodiment, the spacing 152 may be between about 50 mm to about 80 mm when the substrate 122 has a diameter of about 300 mm.

During deposition process, dielectric material may also form on inner surfaces of the physical vapor deposition chamber 100, such as inner surfaces 150 of the shield assembly 128. Dielectric material on inner surfaces 150 may negatively affect the deposition process. According to embodiments of the present invention, a conductive film may be periodically deposited over inner surfaces of the physical vapor deposition chamber 100, such as over the inner surface 150, to prevent negative effects of the dielectric material formed during operation. For example, a pasting process may be performed after processing about 20 to 50 substrates in the physical vapor deposition chamber 100.

FIG. 1B is a schematic sectional side view of the physical vapor deposition chamber 100 in a chamber pasting position according to one embodiment of the present invention. According to one embodiment of the present invention, a conductive coating may be formed over the inner surfaces 150 of the shield assembly 128 by sputtering the target 124 with ions of an inert processing gas, such as argon. During the pasting process, the flow of reactive gas is ceased and only an inert gas is delivered to the processing volume 116 by the gas source 130. A plasma 160 is generated from the inert gas near the target 124 sputtering the conductive material from the target 124 and forming a conductive coating over the inner surfaces 150. To switch from the deposition process to the pasting process according to embodiments of the present invention, one or more process parameters may be adjusted.

According to embodiments of the present invention, spacing between the substrate support 120 and the target 124 is increased from the deposition process to the pasting process. As shown in FIG. 1B, an increased spacing 154 is used during the pasting process so that pasting material may cover larger surface areas on the inner surfaces. The ratio of the spacing 154 for the pasting process and the spacing for deposition process may be between greater than 1.0 and less than 2.0. In one embodiment, the ratio of the spacing 154 and the spacing 152 is about 1.5. In one embodiment, the substrate support 120 may be lowered to obtain a maximum spacing between the target 124 and the substrate support 120 during pasting. The adjustment of spacing may be performed alone or in combination with other adjustments.

According to embodiments of the present invention, the chamber pressure may be increased from the deposition process to the pasting process. Increased chamber pressure results in pasting film with increased thickness. The ratio of chamber pressure for the pasting process and chamber pressure for deposition may be between greater than 1.0 and about 50. For example, the chamber pressure for deposition may be between about 2 mTorr to about 3 mTorr while the chamber pressure for pasting may be between about 20 mTorr to about 100 mTorr. The adjustment of chamber pressure may be performed alone or in combination with spacing adjustment described above.

Prior to the pasting process, a shutter disk 156 may be disposed over the substrate support 120 to protect a substrate contact surface 158 of the substrate support 120. The shutter disk 156 may be formed from a material with a mechanical stiffness sufficient enough to resist deformation due to the coating formed at the pasting process. The material for the shutter disk 156 may be also lightweight to allow easy maneuver by the substrate handlers. In one embodiment, the shutter disk 156 may be formed from aluminum, aluminum alloys, aluminum silicon alloys or other suitable materials.

The conductive target 124 of the physical vapor deposition chamber 100 may be a source for both depositing dielectric materials on substrates during processing and pasting a conductive layer on inner surfaces of physical vapor deposition chamber 100. The pasting process can be easily performed without using additional source.

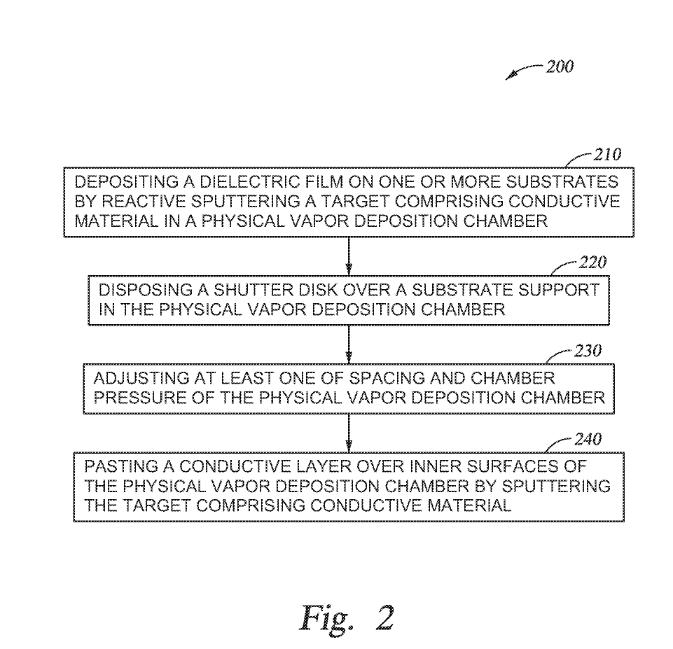

FIG. 2 is a flow chart reflecting a method 200 for depositing a dielectric film using a physical vapor deposition chamber by reactive sputtering according to one embodiment of the present invention. The method 200 may be performed in the physical vapor deposition chamber described in FIGS. 1A-1B.

In box 210, a dielectric film may be deposited on one or more substrates in a physical vapor deposition chamber by reactive sputtering. The dielectric film is formed by reaction of sputtered species from a target in the physical vapor deposition chamber and one or more reactive gas delivered to the physical vapor deposition chamber. The target may be formed from an electrically conductive material, such as a metal or an alloy. The conductive material in the target may be used in pasting process.

During deposition, a gas mixture including a reactive gas and an inert gas may be delivered to the physical vapor deposition chamber from a gas source. A plasma is formed near a front face of the target. The ions in the plasma strike the front face of the target sputtering the conductive material from the target. The sputtered conductive material reacts with the reactive gas in the chamber forming a dielectric material over the substrate being processed.

The dielectric film may include metal nitrides, metal oxides, or combination thereof. The target may include Aluminum, Tantalum, Hafnium, Titanium, Copper, Niobium, or alloys thereof. The reactive gas may include an oxidizing agent, a nitriding agent, or other reactive gases. The inert gas may be argon.

During deposition, the spacing between a substrate supporting surface of the substrate support and the front face of the target may be between about 50 mm to about 80 mm when the substrate has a diameter of about 300 mm. The chamber pressure may be between about 2 mTorr to about 3 mTorr.

The dielectric film may be formed on a plurality of substrates being processed consecutively in the physical vapor deposition chamber. The number of substrates being processed consecutively may be determined by the condition of inner surfaces of the physical vapor deposition chamber. In one embodiment, the number of the plurality of substrates being consecutively processed may be between about 20 to about 50. When enough dielectric material is formed on the inner surfaces, a pasting process may be performed to deposit a conductive coating on the inner surfaces and restore electric conductivities and other properties of the inner surfaces.

In box 220, a shutter disk, such as the shutter disk 156 in FIGS. 1A-1B, may be disposed over the substrate support in place of a substrate being processed to protect the substrate supporting surface of the substrate support.

In box 230, one or more processing parameters may be adjusted alone or in combination for the pasting process. The spacing between the substrate supporting surface of the substrate support and the front face of the target may be increased to provide the inner surfaces being pasted with better exposure to the processing environment. The ratio of the spacing for the pasting process and the spacing for deposition process may be between greater than 1.0 and less than 2.0. In one embodiment, the ratio of the spacing and the spacing is about 1.5. Alternatively, the substrate support may be lowered to obtain a maximum spacing during pasting.

The chamber pressure may be increased from the deposition process to the pasting process. Increased chamber pressure results in pasting film with increased thickness. The ratio of chamber pressure for the pasting process and chamber pressure for deposition may be between greater than 1.0 and about 50. For example, the chamber pressure for deposition may be between about 2 mTorr to about 3 mTorr while the chamber pressure for pasting may be between about 20 mTorr to about 100 mTorr. In one embodiment, both spacing and chamber pressure are adjusted in box 230.

In box 240, a conductive layer is deposited on the inner surfaces of the substrate by sputtering the target with ions of an inert processing gas only. The flow of reactive gas supplied to the physical vapor deposition chamber is ceased during pasting. Only inert gas, such as argon, is supplied to the physical vapor deposition chamber during pasting. To maintain an increased chamber pressure, flow rate of the inert gas may also increase during pasting. A plasma is generated from the inert gas near the target sputtering the conductive material from the target. The sputtered conductive material falls on the inner surfaces of the physical vapor deposition chamber forming a conductive coating.

After the pasting process in box 240, the shutter disk is removed from the substrate support and a plurality of substrates may be processed consecutively as described in box 210.

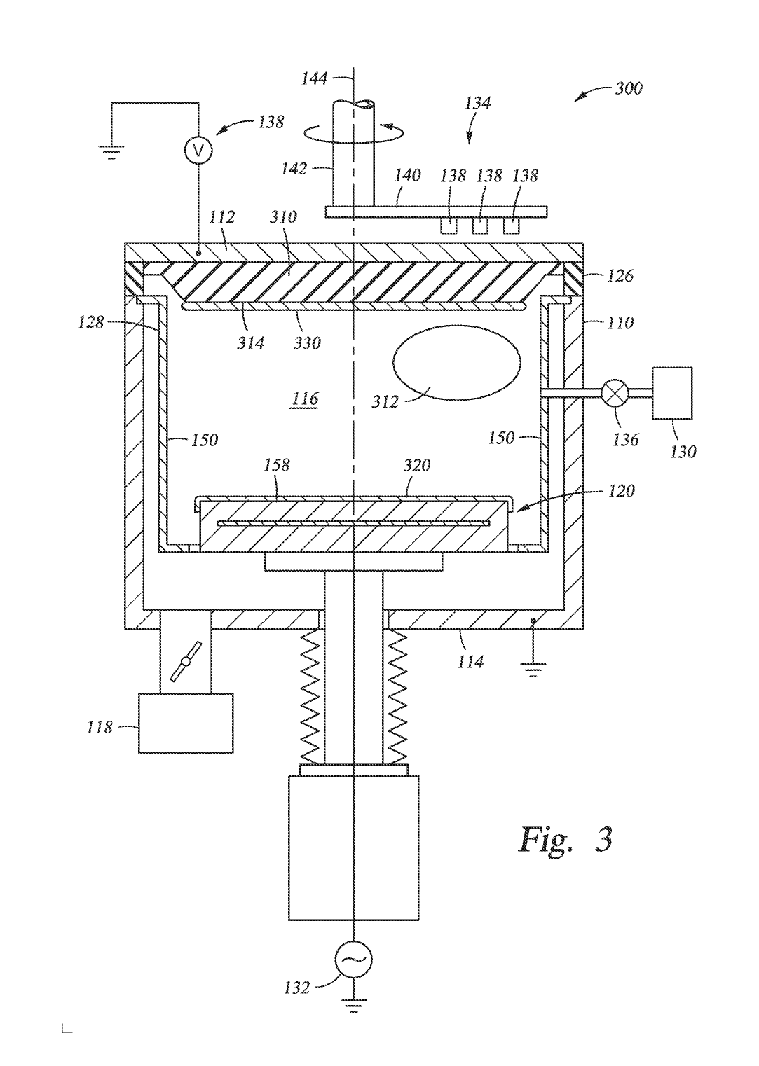

FIG. 3 is a sectional side view of a physical vapor deposition chamber 300 according to another embodiment of the present invention. The physical vapor deposition chamber 300 is similar to the physical vapor deposition chamber 100 described in FIGS. 1A-1B except that the physical vapor deposition chamber 300 includes a composite target 310 for depositing a dielectric material on a substrate. The composite target 310 is not electrically conductive. The DC power source 138 may be coupled to the chamber lid 112. During deposition process, an inert gas is delivered to the chamber volume 116 and a plasma 312 is formed near a front face 314 of the target 310. Ions in the plasma 312 strike the front face 314 of the target 310 sputtering the composite material, which falls on the substrate being processed forming a dielectric material over thereon.

The target 310 may be formed from metal oxides, metal nitrides, or combinations thereof. The target 310 may include nitrides or oxides of Aluminum, Tantalum, Hafnium, Titanium, Copper, Niobium, or other suitable metals. The target 310 may be formed from composite materials such as indium tin oxide (ITO) and Ge₂Sb₂Te₅ (GST).

During deposition, some dielectric material may be formed on inner surfaces 150 of the physical vapor deposition chamber 300 and negatively affect the deposition process. According to embodiments of the present invention, a conductive film may be periodically deposited over inner surfaces of the physical vapor deposition chamber 300, such as over the inner surface 150, to prevent negative effects of the dielectric material formed during operation. For example, a pasting process may be performed after processing about 20 to 50 substrates in the physical vapor deposition chamber 300.

FIG. 3 schematically illustrates the physical vapor deposition chamber 300 in the pasting position. During pasting, a shutter disk 330 may be disposed over the target 310 to prevent any deposition of conductive material from forming on the target 310. A shutter disk 320 may be disposed over the substrate support 120 to protect the substrate supporting surface 156.

Because the target 310 is not formed from conductive material, a separate source may be used for the pasting process. In one embodiment, one of the shutter disks 320, 330 is used as a source for forming a conductive coating over the inner surfaces 150.

In one embodiment, the shutter disk 330 is used as a source for the conductive coating. During pasting process, an inert gas is delivered to the processing volume 116 by the gas source 130. A plasma 312 is generated from the inert gas near the shutter disk 330 sputtering the conductive material from the shutter disk 330 and forming a conductive coating over the inner surfaces 150. When used as a conductive source, the shutter disk 330 may be formed from one or more metals, such as Aluminum, Tantalum, Hafnium, Titanium, Copper, Niobium, or other suitable metals. In one embodiment, the shutter disk 330 is made of aluminum or aluminum alloy.

In another embodiment, the shutter disk 320 disposed over the substrate support 320 is used as a source for the conductive coating. During pasting process, an inert gas is delivered to the processing volume 116 by the gas source 130. The physical vapor deposition chamber 300 is reverse biased so that ions in the plasma generated from the inert gas strike the shutter disk 320 to sputter the conductive material from the shutter disk 320. When used as a conductive source, the shutter disk 320 may be formed from one or more metals, such as Aluminum, Tantalum, Hafnium, Titanium, Copper, Niobium, or other suitable metals. In one embodiment, the shutter disk 320 is made of aluminum or aluminum alloy.

Similar to the pasting process performed in the physical vapor deposition chamber 100, one or more processing parameters may be adjusted alone or in combination for pasting the physical vapor deposition chamber 300. Particularly, the spacing and/or chamber pressure may be increased during pasting.

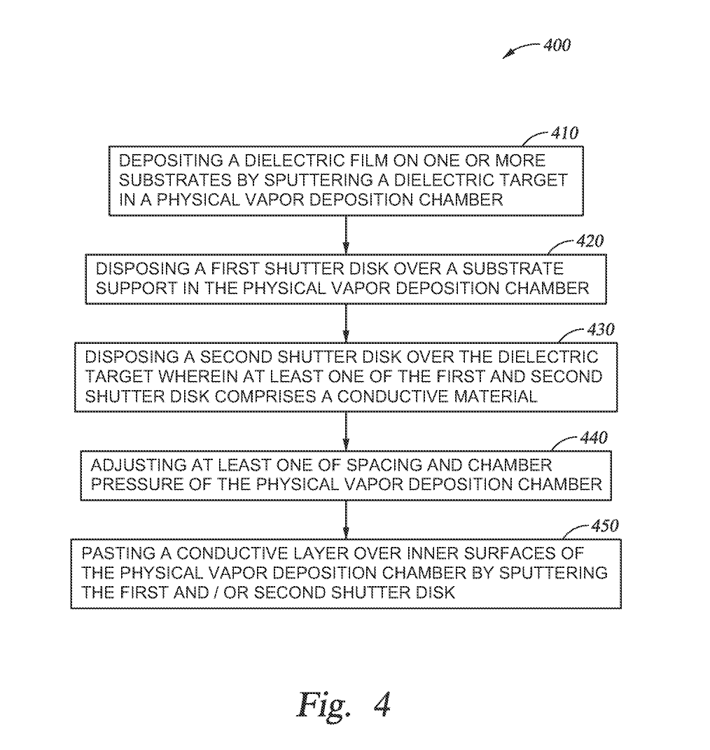

FIG. 4 is a flow chart reflecting a method 400 for depositing a dielectric film by sputtering using a physical vapor deposition chamber similar to the physical vapor deposition chamber 300.

In box 410, a dielectric film may be deposited on one or more substrates in a physical vapor deposition chamber by sputtering. The dielectric film is formed by striking a target formed from the dielectric material using ions of an inert gas, such as argon.

During deposition, an inert gas may be delivered to the physical vapor deposition chamber from a gas source. A plasma is formed near a front face of the target. The ions in the plasma strike the front face of the target sputtering the dielectric material and the sputtered dielectric material then forms a dielectric material over the substrate being processed.

The dielectric film may include metal nitrides, metal oxides, or combination thereof. The target may include oxides or nitrides of Aluminum, Tantalum, Hafnium, Titanium, Copper, Niobium, or alloys thereof.

During deposition, the spacing between a substrate supporting surface of the substrate support and the front face of the target may be between about 50 mm to about 80 mm when the substrate has a diameter of about 300 mm. The chamber pressure may be between about 2 mTorr to about 3 mTorr.

The dielectric film may be formed on a plurality of substrates being processed consecutively in the physical vapor deposition chamber. When enough dielectric material is formed on the inner surfaces, a pasting process may be performed to deposit a conductive coating on the inner surfaces and restore electric conductivities and other properties of the inner surfaces.

In box 420, a first shutter disk may be disposed over the substrate support in place of a substrate being processed to protect the substrate supporting surface of the substrate support.

In box 430, a second shutter disk may be disposed over the target to protect the target deposition of any conductive material during pasting.

In box 440, one or more processing parameters may be adjusted alone or in combination for the pasting process, similar to box 230. The spacing between the substrate supporting surface of the substrate support and the front face of the target may be increased to provide the inner surfaces being pasted with better exposure to the processing environment. The chamber pressure may be increased from the deposition process to the pasting process.

In box 450, a conductive layer is deposited on the inner surfaces of the substrate by sputtering the first shutter disk or the second shutter disk with ions of an inert processing gas only. Ions from the plasma of the inert gas near strike the first or second shutter disk sputtering the conductive material therefrom. The sputtered conductive material falls on the inner surfaces of the physical vapor deposition chamber forming a conductive coating.

While the foregoing is directed to embodiments of the present invention, other and further embodiments of the invention may be devised without departing from the basic scope thereof, and the scope thereof is determined by the claims that follow.

1. A method for forming a dielectric material, comprising:
disposing a shutter disk over a substrate support of a physical vapor deposition chamber having a target for depositing a dielectric material;
adjusting at least one of spacing between the substrate support and the target and a chamber pressure; and
pasting a conductive layer over inner surfaces of the physical vapor deposition chamber by sputtering the target or the shutter disk.

2. The method of claim 1, wherein adjusting the at least one of spacing and a chamber pressure comprises increasing the spacing between the substrate support and the target.

3. The method of claim 2, wherein the ratio of spacing during pasting to spacing during depositing is between about greater than 1.0 to about 2.0.

4. The method of claim 1, wherein the adjusting at least one of spacing and a chamber pressure comprises increasing chamber pressure.

5. The method of claim 4, wherein the ratio of chamber pressure during pasting to chamber pressure during depositing the dielectric material is between about greater than 1.0 to about 50.

6. The method of claim 1, further comprising depositing the dielectric material by sputtering the target, wherein the target comprises a conductive material, and depositing the dielectric material is performed by reactive sputtering of the target with a plasma activated from a processing gas comprising a reactive gas.

7. The method of claim 6, wherein pasting the conductive layer comprises sputtering the target to sputter the conductive material using a plasma activated from an inert gas.

8. The method of claim 6, wherein the target is formed from Aluminum, Tantalum, Hafnium, Titanium, Copper, Niobium, or alloys thereof.

9. The method of claim 6, wherein the reactive gas comprises oxygen and/or nitrogen.

10. The method of claim 1, further comprising depositing the dielectric material by sputtering the target, wherein the target comprises a dielectric material, and depositing the dielectric material is performed by sputtering of the target with a plasma activated from an inert gas.

11. The method of claim 10, further comprising disposing an additional shutter disk over a surface of the target prior to pasting a conductive layer.

12. The method of claim 11, wherein the additional shutter disk is formed from a conductive material, and the pasting a conductive layer comprises striking the additional shutter disk with ions of the inert gas.

13. The method of claim 11, wherein the shutter disk is formed from a conductive material, and the pasting a conductive layer comprises striking the shutter disk with ions of the inert gas.

14. A method for forming a dielectric material, comprising:
flowing a reactive gas and an inert gas into a physical vapor deposition chamber having a target comprising a conductive material;
generating a plasma of the reactive gas and the inert gas to sputter the target and depositing a dielectric film on the substrate disposed on a substrate support in the physical vapor deposition chamber by reactive sputtering;
ceasing the flow of the reactive gas;
adjusting at least one of a chamber pressure and a spacing between the substrate support and the target; and
generating a plasma of the inert gas to sputter the target and to paste a conductive film on inner surfaces of the physical vapor deposition chamber.

15. The method of claim 14, wherein the adjusting at least one of spacing and a chamber pressure comprises increasing the spacing between the substrate support and the target.

16. The method of claim 15, wherein the adjusting at least one of spacing and a chamber pressure comprises increasing chamber pressure.

17. A method for forming a dielectric material, comprising:
flowing an inert gas towards a physical vapor deposition chamber having a target comprising a dielectric material;
generating a plasma of the inert gas to sputter the target and depositing a dielectric film on the substrate disposed on a substrate support in the physical vapor deposition chamber;
disposing a first shutter disk over the target;
disposing a second shutter disk over the substrate support;
adjusting at least one of a chamber pressure and a spacing between the substrate support and the target; and
generating a plasma of the inert gas to sputter the first shutter disk or the second shutter disk and to paste a conductive film on inner surfaces of the physical vapor deposition chamber.

18. The method of claim 17, wherein the adjusting at least one of spacing and a chamber pressure comprises increasing the spacing between the substrate support and the target.

19. The method of claim 18, wherein the adjusting at least one of spacing and a chamber pressure comprises increasing chamber pressure.

20. The method of claim 18, wherein generating a plasma comprises using a magnetron disposed over the target.
